(19) United States
(12) Patent Application Publication
(10) Pub. No.: US 2011/0278687 A1
(43) Pub. Date: Nov. 17, 2011

(54) BACKSIDE-ILLUMINATED SENSOR WITH NOISE REDUCTION

(76) Inventors: Fang-Ming Huang, Grand Cayman (KY); Ping-Hung Yin, Grand Cayman (KY); Chung-Wei Chang, Grand Cayman (KY)

(21) Appl. No.: 12/781,785

(22) Filed: May 17, 2010

(51) Int. Cl. H01L 31/0232; H01L 31/00

(52) U.S. Cl. 257/432; 257/460; 257/E31.127

(57) ABSTRACT

A backside-illuminated sensor includes a substrate, at least one lens and at least one pixel structure. The substrate has a front surface and a backside surface, and the lens is formed on the backside surface of the substrate and the pixel structure is formed on a pixel area included in the front surface of the substrate, where a projected area of the pixel area on the backside surface in a thickness direction of the substrate is covered by the lens. The pixel structure includes a first power node for receiving a first supply voltage, a second power node for receiving a second supply voltage different from the first supply voltage, a sensing element and a capacitor for noise reduction. The sensing element generates a sensing signal according to an incident luminance from the lens.

### BACKGROUND OF THE INVENTION

1. Field of the Invention

The present invention relates to an image sensor, and more particularly, to a backside-illuminated sensor with noise reduction.

2. Description of the Prior Art

As the pixel size of a complementary metal-oxide-semiconductor image sensor (CMOS image sensor, CIS) grows smaller, the degradation resulting from certain factors such as quantum efficiency, cross-talk and dark current in a sensor array also becomes significant. Regarding a conventional image sensor such as a front side illuminated sensor, a lens of each pixel sensor is fabricated on a front side of a substrate. Therefore, the incident light has to travel through dielectric layers between circuitry formed by metal layers to arrive at a photo diode, or the traveling light will be reflected or absorbed by metal or any other reflective material. Since the traveling path of light cannot be blocked by metal or any other kind of reflective material, there is no vacancy for accommodating additional noise reduction circuitry.

Please refer to FIG. 1, which is a cross-section view of a pixel structure of a conventional front side illuminated image sensor array. As shown in FIG. 1, an incident light travels through a micro lens ML, a color filter CL, dielectric layers and a silicon substrate Si which has a photo diode P to collect and convert the incident light into electrical signals. A contact layer CO and metal layers M1, M2 should not be in the path of the incident light, or the photo diode P cannot function in the most efficient way. As a result, only a few spaces can be utilized for routing traces on the metal layers, and therefore certain functionalities, such as noise reduction and voltage regulation, are hard to achieve.

### SUMMARY OF THE INVENTION

In light of this, the present invention provides a backside-illuminated (BSI) sensor with a simple noise reduction element capable of efficiently reducing noise.

According to one embodiment of the present invention, an exemplary backside-illuminated sensor is provided. The exemplary BSI sensor comprises a substrate, at least one lens and at least one pixel structure. The substrate has a front surface and a backside surface, the lens is formed on the backside surface of the substrate and the pixel structure is formed on a pixel area included in the front surface of the substrate, wherein a projected area of the pixel area on the backside surface in a thickness direction of the substrate is covered by the lens. The pixel structure has a first power node, a second power node, a sensing element and a capacitor. The first power node is for receiving a first supply voltage and the second power node is for receiving a second supply voltage different from the first supply voltage. The sensing element generates a sensing signal according to an incident luminance from the lens. The noise reduction element is coupled between the first power node and the second power node. The capacitor includes a first metal element and a second metal element and a dielectric element, wherein the first metal element is coupled to the first power node, and the second metal element is coupled to the second power node, and the dielectric element is located between the first metal layer and the second metal layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross-section view of a pixel structure of a conventional front side illuminated image sensor array.

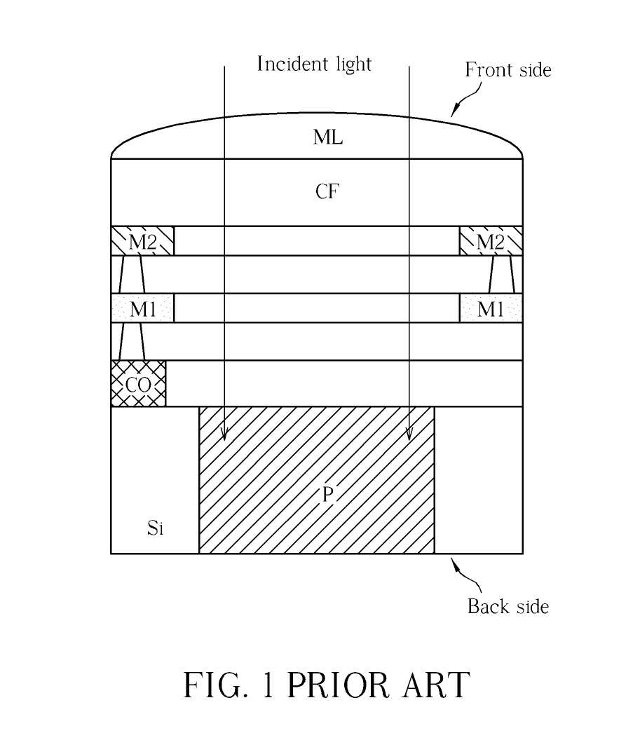

FIG. 2 is a cross-section view of a pixel structure of a backside illuminated sensor array according to an embodiment of the present invention.

FIG. 3 is a circuit diagram of a pixel structure according to an embodiment of the present invention.

FIG. 4 is a structural diagram of a noise reduction element according to an embodiment of the present invention.

FIG. 5 is a cross-section view of the noise reduction element according to another embodiment of the present invention.

FIG. 6 is a three-dimensional diagram of the noise reduction element according to yet another embodiment of the present invention.

### DETAILED DESCRIPTION

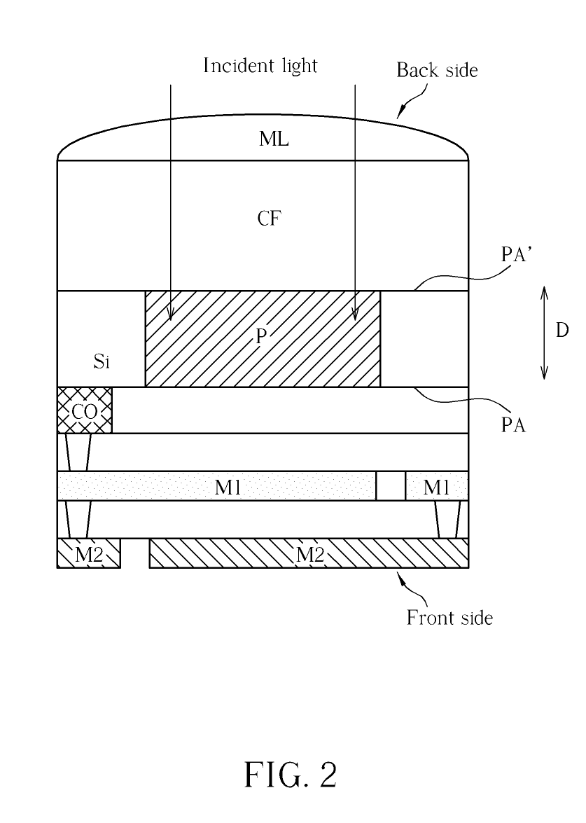

Please refer to FIG. 2, which is a cross-section view of a pixel structure of a backside illuminated (BSI) sensor array according to an embodiment of the present invention. As shown in FIG. 2, an incident light travels through a micro lens ML, a color filter CL, and ends up being projected directly onto a photo diode Pin the substrate Si. Since the incident light is projected from the backside of the substrate Si, the metal layers M1, M2 and other circuitries are on the opposite side of the substrate Si and are much easier to have traces routed thereon. Therefore, the metal layers M1 and M2 can be utilized to improve the overall sensing performance.

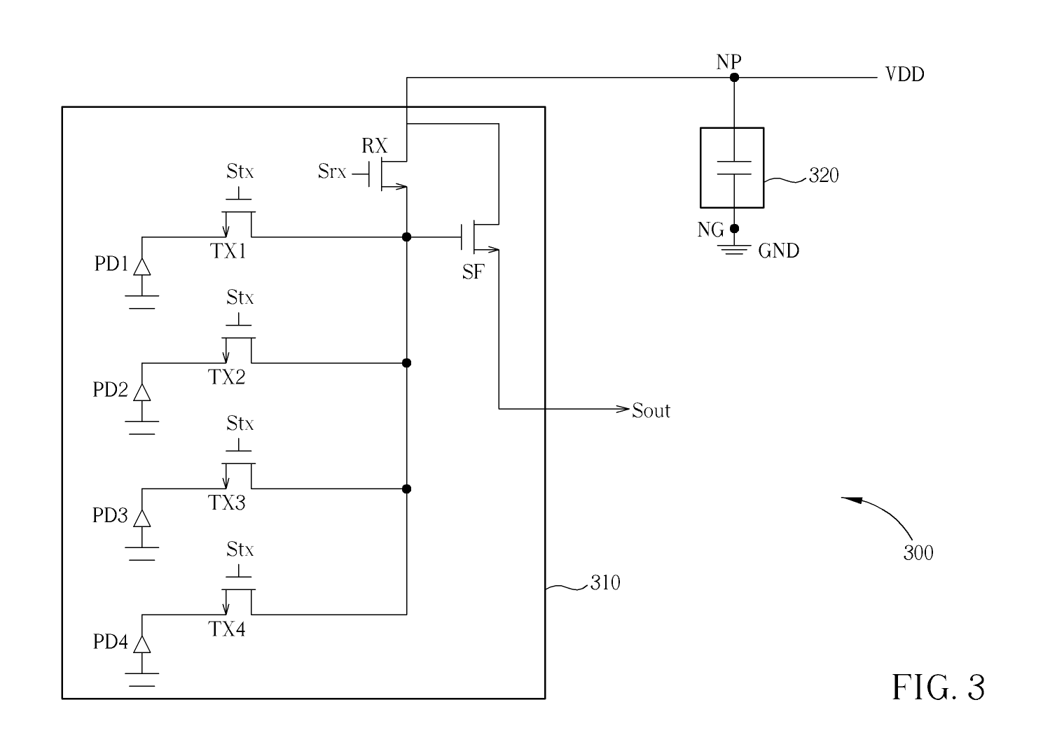

Please refer to FIG. 3, which is a circuit diagram of a pixel structure 300 according to an embodiment of the present invention. The pixel structure 300 is formed on a pixel area PA included in a front surface of the substrate Si. Due to the BSI sensor structure, a projected area PA′ of the pixel area PA on a backside surface of the substrate Si in a thickness direction D of the substrate Si will be covered by the micro lens ML. The pixel structure 300 includes, but is not limited to, a first power node NP for receiving a supply voltage VDD, a second power node NG for receiving a ground voltage GND, a sensing element 310 and a noise reduction element 320, connected between the supply voltage VDD and the ground voltage GND. The sensing element 310 includes a reset transistor Rx, an output transistor SF, four transfer transistors Tx1˜TX4 and four photo diodes PD1˜PD4 corresponding to the transfer transistors Tx1˜TX4, respectively. The reset transistor Rx has a control node for receiving a reset instruction Srx, a first node coupled to the supply voltage VDD, and a second node. Each of the transfer transistors Tx1˜Tx4 has a control node for receiving a transfer instruction Stx, a first node coupled to the second node of the reset transistor Rx, and a second node. Each of the photo diodes PD1˜PD4 (which correspond to transfer transistors Tx1˜Tx4, respectively) has a first node coupled to the ground voltage GND and a second node coupled to the second node of the corresponding transfer transistor. The output transistor SF, which is a source follower in this embodiment, has a control node coupled to the second node of the reset transistor Rx and the first node of each of the transfer transistors Tx1˜Tx4, a first node coupled to a terminal of the noise reduction element 320, and a second node for outputting a sensing signal Sout. When the sensing function is activated, each of the photo diodes PD1˜PD4 receives the incident light and converts the incident light into an electrical signal accordingly. Each of the transfer transistors Tx1˜TX4 is activated by the transfer instruction Stx and transfers the electrical signals from the corresponding photo diodes PD1˜PD4 to the output transistor SF. In this embodiment, the output transistor SF serves as a buffer and delivers the sensing signal Sout to a following processing apparatus according to a sum of the electrical signals transmitted via the transfer transistors Tx1˜TX4.

When the transfer transistors Tx1˜TX4 receive the transfer instruction Stx via corresponding control nodes, the transfer transistors Tx1˜TX4 transfer the converted signal s to the output transistor SF, and the output transistor SF thereby outputs the sensing signal Sout according to the sum of the signals from the transfer transistors Tx1˜TX4. When the reset instruction Srx is enabled, the reset transistor Rx will force the control node (e.g., gate terminal) of the output transistor SF to a predetermined voltage level (in this embodiment, the predetermined voltage level at the control node of the output transistor SF is high), and therefore the output signal Sout is fixed at a predetermined value.

Since, however, the output transistor SF serves as a source follower, any fluctuation at the first node (e.g., drain terminal) of the output transistor SF may degrade the output signal Sout. Regarding conventional front side illuminated image sensors, delicate noise reduction circuitry is almost impossible since the majority of space is reserved for the path of incident light. As a result, for front side illuminated image sensors, the output transistors suffer from noise injected from reference voltages. Please refer to FIG. 2 again. In this embodiment, the incident light is projected from the backside of the substrate Si, and metal layers and dielectrics in between can be utilized for performance enhancement without blocking the incident light (for example: the metal layers M1 and M2 in FIG. 2 can have traces routed freely to form a capacitor or interact with other circuit elements). In FIG. 3, a noise reduction element 320 is introduced. In this embodiment, the noise reduction element 320 is implemented by a capacitor to provide a simple and elegant solution for stabilizing the supply voltage VDD and achieving power noise reduction; however, this is not supposed to be a limitation to the present invention. For example, a more sophisticated structure can be achieved with additional circuitry; additionally, the target of noise reduction is not limited to power noise.

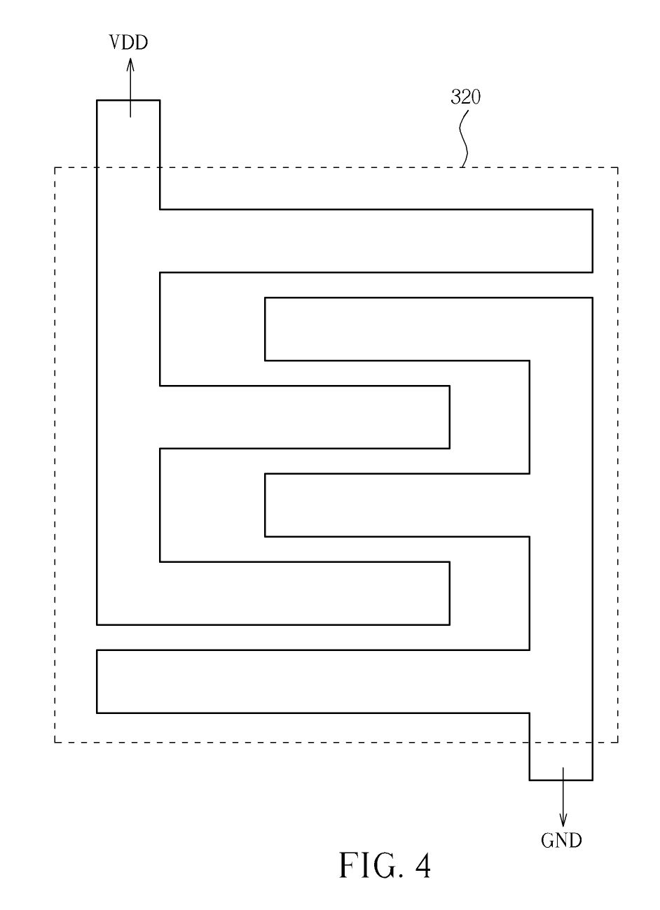

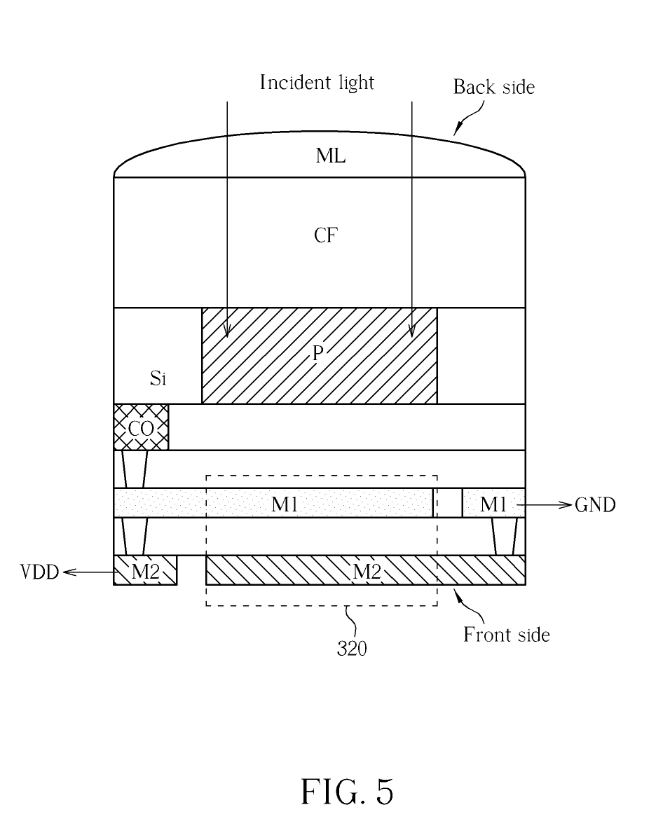

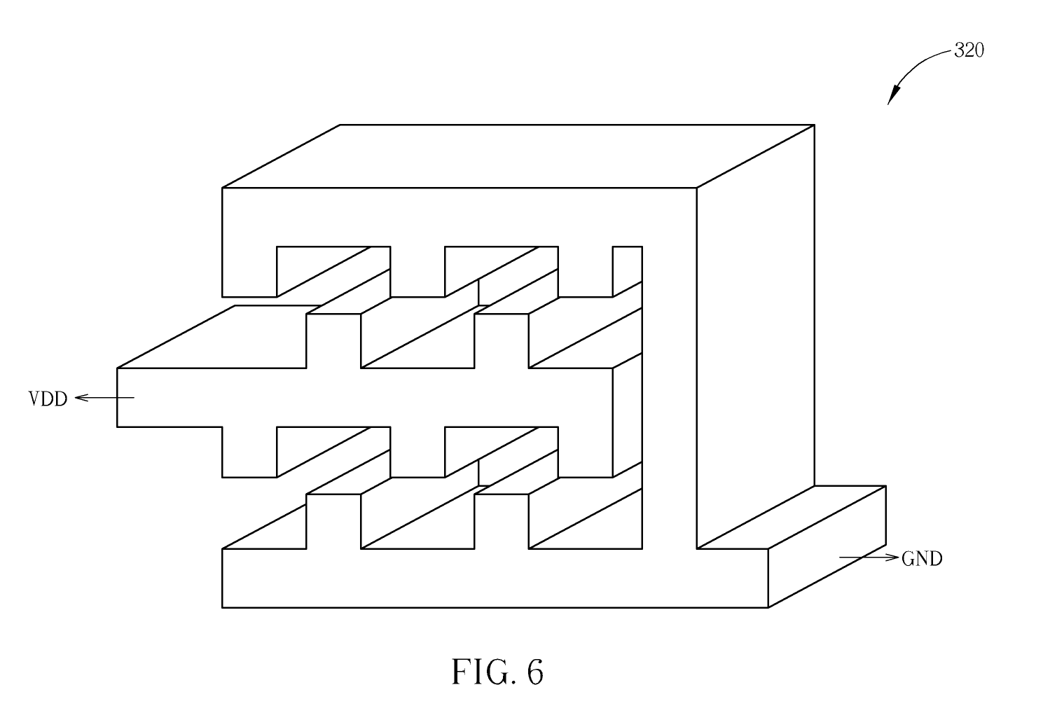

The noise reduction element 320 can be implemented in a variety of forms such as a metal-oxide-metal (MOM) capacitor, a metal-insulator-metal (MIM) capacitor, or a combination of both. For illustrations of these, please refer to FIG. 4, FIG. 5 and FIG. 6, respectively. FIG. 4 is a structural diagram of the noise reduction element 320 according to an embodiment of the present invention, FIG. 5 is a cross-section view of the noise reduction element 320 according to another embodiment of the present invention, and FIG. 6 is a three-dimensional diagram of the noise reduction element 320 according to yet another embodiment of the present invention. In FIG. 4, the noise reduction element 320 is shaped as an interdigital capacitor formed by metal layer Ml (or metal layer M2). In FIG. 5, the noise reduction element 320 is an MIM capacitor formed by metal layer M1, metal layer M2 and a dielectric in between. In FIG. 6, the noise reduction element 320 is a capacitor formed by three metal layers, via contacts and dielectrics in between. In short, any backside-illuminated sensor which utilizes at least one metal layer along with dielectrics and oxides falls within the scope of the present invention.

In summary, the present invention provides a backside-illuminated sensor with a simple noise reduction element for noise reduction. The noise reduction element can be implemented by an MIM capacitor, an MOM capacitor, or a capacitor formed by a plurality of metal layers and dielectric layers in between.

Those skilled in the art will readily observe that numerous modifications and alterations of the device and method may be made while retaining the teachings of the invention.

What is claimed is:

1. A backside-illuminated (BSI) sensor, comprising:
a substrate having a front surface and a backside surface;
at least one lens, formed on the backside surface of the substrate; and
at least one pixel structure, formed on a pixel area included in the front surface of the substrate, wherein a projected area of the pixel area on the backside surface in a thickness direction of the substrate is covered by the at least one lens, and the at least one pixel structure comprises:
a first power node for receiving a first supply voltage;
a second power node for receiving a second supply voltage different from the first supply voltage;
a sensing element, coupled to the first power node and the second power node, for generating a sensing signal according to an incident luminance from the at least one lens; and
a capacitor, comprising:
a first metal element coupled to the first power node;
a second metal element coupled to the second power node; and
a dielectric element between the first metal layer and the second metal layer.

2. The backside-illuminated sensor of claim 1, wherein the first metal element and the second metal element of the capacitor are formed by a single metal layer.

3. The backside-illuminated sensor of claim 1, wherein the first metal element and the second metal element of the capacitor are formed by a plurality of metal layers.

4. The backside-illuminated sensor of claim 1, wherein the capacitor is a metal-oxide-metal (MOM) capacitor.

5. The backside-illuminated sensor of claim 1, wherein the capacitor is a metal-insulator-metal (MIM) capacitor.

6. The backside-illuminated sensor of claim 1, wherein the sensing element comprises:
a reset transistor, having a control node for receiving a reset instruction, a first node coupled to the first power node, and a second node;
at least one transfer transistor, having a control node for receiving a transfer instruction, a first node coupled to the second node of the reset transistor, and a second node;
at least one photo diode, having a first node coupled to the second power node and a second node coupled to the second node of the at least one transfer transistor; and
an output transistor, having a control node coupled to the second node of the reset transistor and the first node of the at least one transfer transistor, a first node coupled to one end of the capacitor, and a second node for outputting the sensing signal.

7. The backside-illuminated sensor of claim 6, wherein the output transistor is a source follower.
